(19) United States
(12) Patent Application Publication
(10) Pub. No.: US 2025/0282610 A1
(43) Pub. Date: Sep. 11, 2025

(54) SEMICONDUCTOR DEVICE AND METHOD FOR MANUFACTURING THE SAME

(71) Applicant: Murata Manufacturing co., Ltd., Nagaokakyo-shi (JP)

(72) Inventor: Ryosuke NIWA, Nagaokakyo-shi (JP)

(21) Appl. No.: 19/216,903

(22) Filed: May 23, 2025

Related U.S. Application Data
(63) Continuation of application No. PCT/JP2023/037738, filed on Oct. 18, 2023.

(30) Foreign Application Priority Data
Dec. 28, 2022 (JP) 2022-211859

(51) Int. Cl. B81B 7/00; B81C 1/00; H01L 21/56; H01L 23/00; H01L 23/29; H01L 25/16; H05K 1/18

(52) U.S. Cl. CPC B81B 7/0032; B81C 1/00888; H01L 21/566; H01L 23/29; H01L 23/564; B81B 2201/0264; H01L 24/16; H01L 24/48; H01L 24/49; H01L 25/16; H01L 2224/16227; H01L 2224/16238; H01L 2224/48229; H01L 2224/49175; H01L 2924/1461; H05K 1/181

(57) ABSTRACT

A semiconductor device that includes: a base member; a detecting element on the base member and having a first surface with a detector; an insulating protective film covering the detector and the first surface; and a resin package on the base member and including an exposure hole exposing the detector to an outside, a portion of the resin package covering the detecting element such that at least a portion of an outer periphery of the first surface is exposed through the exposure hole, and the resin package includes a recess extending along the portion of the outer periphery exposed through the exposure hole. The detecting element has: a second surface extending from the outer periphery toward the base member, a third surface extending outward from the second surface, and a fourth surface extending from the third surface toward the base member, and wherein the protective film covers the second surface.

### CROSS REFERENCE TO RELATED APPLICATIONS

The present application is a continuation of International application No. PCT/JP2023/037738, filed Oct. 18, 2023, which claims priority to Japanese Patent Application No. 2022-211859, filed Dec. 28, 2022, the entire contents of each of which are incorporated herein by reference.

### TECHNICAL FIELD

The present disclosure relates to a semiconductor device including a resin package and a method for manufacturing the same.

### BACKGROUND ART

For example, Patent Document 1 discloses a semiconductor device. The semiconductor device includes a detecting element disposed on a base member and having a first surface at which a detector is disposed, and a resin package disposed on the base member and having an exposure hole for allowing the detector to be exposed to the outside. In the semiconductor device, the detecting element has a recess formed at the outer periphery of the first surface.

In the process of manufacturing the semiconductor device disclosed in Patent Document 1, a wall-shaped portion is formed around the detector by thrusting the detecting element into a release film that closely adheres to the surface of a die. In this structure, the wall-shaped portion reduces the resin material that is to cover the detector during a subsequent operation of filling of the resin material. After the resin material cures to form the resin package, and the die is removed, the portion where the wall-shaped portion is formed serves as the recess.
Patent Document 1: International Publication No. 2021/049138

### SUMMARY OF THE DISCLOSURE

In the semiconductor device disclosed in Patent Document 1, a portion of the detecting element exposed to the outside (a first surface of the detecting element including the detector) is waterproofed by a passivation film (a protective film).

However, the semiconductor device disclosed in Patent Document 1 has a recess at the outer periphery of an upper surface of the detecting element. This recess may allow a portion of the side surface (the surface extending downward from the outer edge of the first surface) of the detecting element, particularly, a portion located near the first surface of the detecting element to be exposed without being covered with the resin package. Thus, the exposed side surface of the detecting element may come into contact with water. In other words, the detecting element may fail to be waterproofed.

Thus, the present disclosure aims to solve the above issue, and to provide a semiconductor device capable of reducing degradation of waterproofness of the detecting element, and a method for manufacturing the semiconductor device.

In order to achieve the above object, the present disclosure has the structure described below.

A semiconductor device according to an aspect of the present disclosure includes: a base member; a detecting element on the base member and having a first surface with a detector; an insulating protective film that covers the detector and the first surface; and a resin package on the base member and including an exposure hole that exposes the detector of the detecting element to an outside with the protective film interposed therebetween, a portion of the resin package excluding the exposure hole covering the detecting element such that at least a portion of an outer periphery of the first surface is exposed through the exposure hole, and the resin package includes a recess extending along the portion of the outer periphery exposed through the exposure hole, wherein the detecting element further has: a second surface extending from the outer periphery toward the base member, a third surface extending outward from the second surface when viewed in a direction orthogonal to the first surface, and a fourth surface extending from the third surface toward the base member, and wherein the protective film covers the second surface.

A method for manufacturing a semiconductor device according to an aspect of the present disclosure includes: forming a first groove in a main surface of a base portion to divide the main surface into a plurality of areas; covering the main surface including the first groove with an insulating protective film; cutting the base portion covered with the protective film along the first groove to divide the base portion into a plurality of detecting elements each having a first surface with a detector; placing each of the detecting elements on a base member; adhering a release film to a die having a cavity with a protrusion; placing the die with respect to the base member while the first surface of the detecting elements is thrust into a portion of the release film on a surface of the protrusion; filling the cavity of the die with a resin material; and detaching the die and the release film from a resin package formed from the resin material after curing, wherein at least a portion of an outer periphery of the surface of the protrusion is located outward from an outer periphery of the first surface when viewed in a direction in which the protrusion of the die and the first surface of the detecting element face each other.

The present disclosure can reduce degradation of waterproofness of the detecting element.

### BRIEF DESCRIPTION OF THE DRAWINGS

FIG. 1 is a perspective view of a semiconductor device according to a first embodiment of the present disclosure.

FIG. 2 is a top view of the semiconductor device according to the first embodiment of the present disclosure.

FIG. 3A is a cross-sectional view of the semiconductor device taken along line A-A in FIG. 2.

FIG. 3B is a cross-sectional view of the semiconductor device taken along line B-B in FIG. 2.

FIG. 4 is an enlarged view of a portion enclosed by a broken line in FIG. 3B.

FIG. 5A is a diagram illustrating one process in the manufacture of a detecting element.

FIG. 5B is a diagram illustrating one process in the manufacture of the detecting element, following the process in FIG. 5A.

FIG. 5C is a diagram illustrating one process in the manufacture of the detecting element, following the process in FIG. 5B.

FIG. 5D is a diagram illustrating one process in the manufacture of the detecting element, following the process in FIG. 5C.

FIG. 6A is a diagram illustrating one process in the manufacture of a resin package.

FIG. 6B is a diagram illustrating one process in the manufacture of the resin package, following the process in FIG. 6A.

FIG. 6C is a diagram illustrating one process in the manufacture of the resin package, following the process in

FIG. 6B.

FIG. 6D is a diagram illustrating one process in the manufacture of the resin package, following the process in

FIG. 6C.

FIG. 7 is a top view of the semiconductor device, illustrating the positional relationship and the dimensional relationship between a die and the detecting element.

FIG. 8 is a diagram illustrating the process illustrated in FIG. 6C, and another cross-sectional view of the semiconductor device.

FIG. 9 is a top view of a semiconductor device according to a second embodiment of the present disclosure.

FIG. 10A is a cross-sectional view of the semiconductor device taken along line A-A illustrated in FIG. 9.

FIG. 10B is a cross-sectional view of the semiconductor device taken along line B-B illustrated in FIG. 9.

### DESCRIPTION OF THE PREFERRED EMBODIMENTS

### First Embodiment

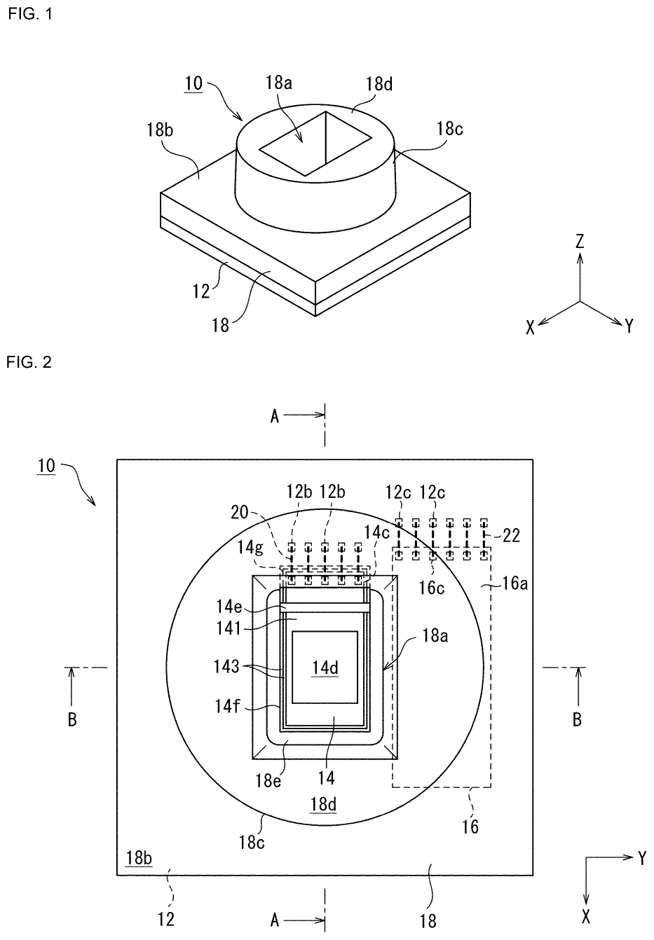

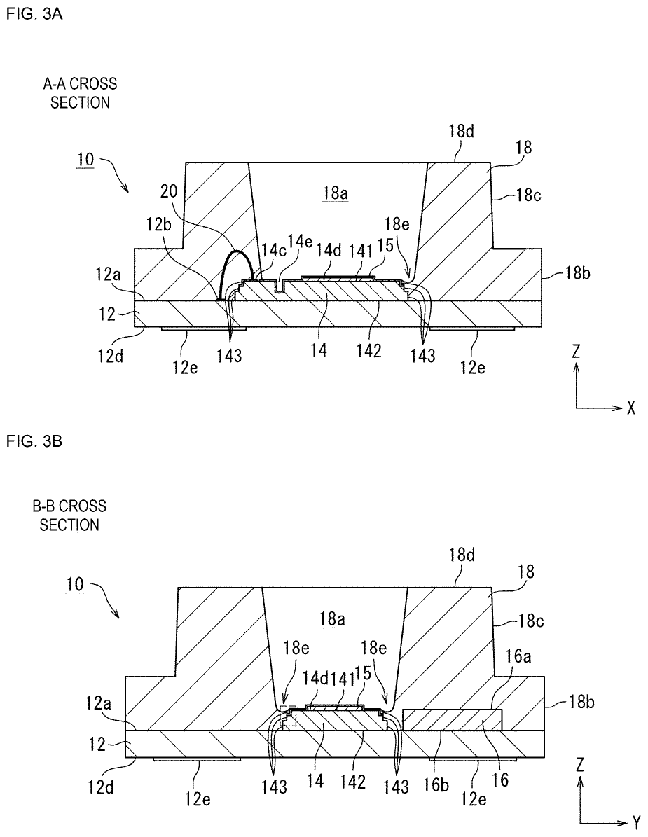

FIG. 1 is a perspective view of a semiconductor device according to a first embodiment of the present disclosure. FIG. 2 is a top view of the semiconductor device according to the first embodiment of the present disclosure. FIG. 3A and FIG. 3B are cross-sectional views of the semiconductor device according to the first embodiment, respectively taken along line A-A and line B-B in FIG. 2. The X-Y-Z orthogonal coordinate system illustrated in these drawings is provided for ease of understanding the present disclosure, not to limit the disclosure.

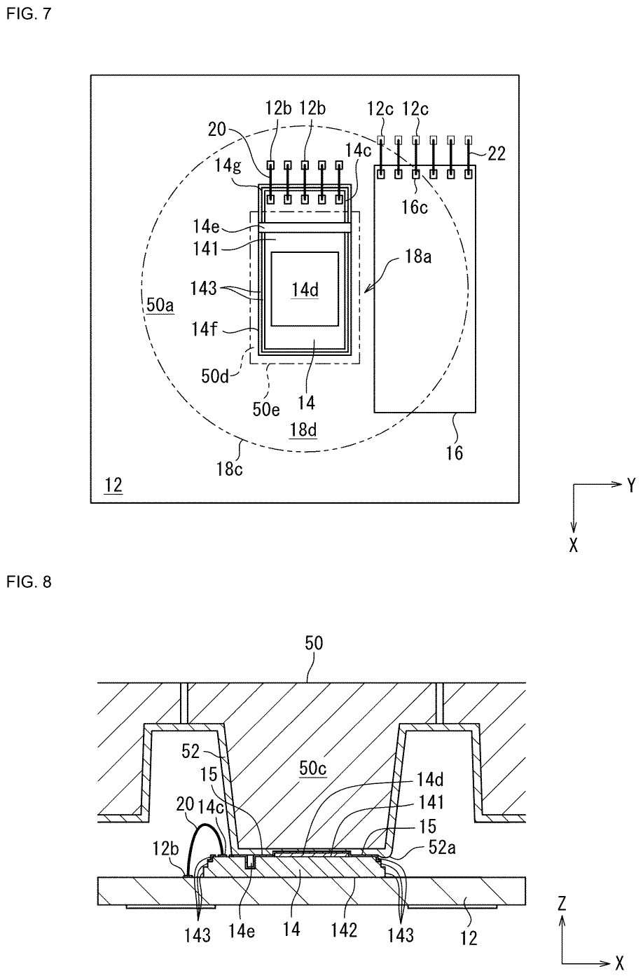

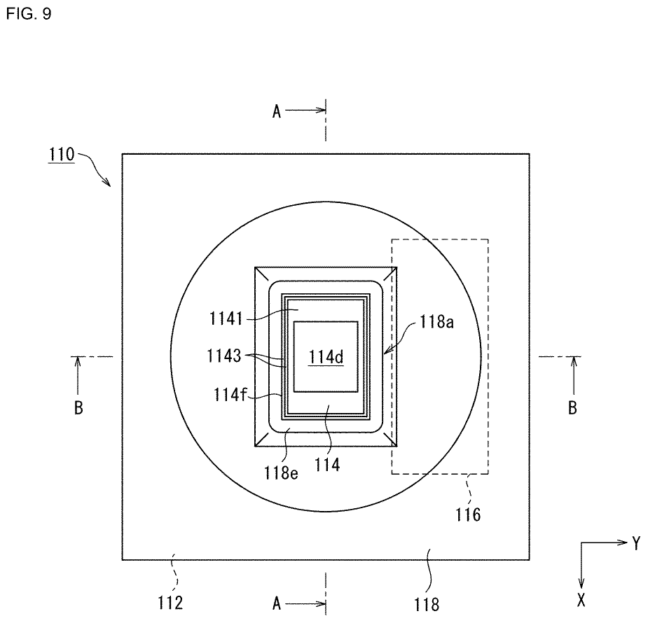

As illustrated in FIG. 1 to FIG. 3, a semiconductor device 10 according to the first embodiment is a pressure sensor that measures the pressure, and includes a base member 12, a detecting element 14 disposed on the base member 12, and a protective film 15 that covers a portion of the detecting element 14. In the first embodiment, a circuit element 16 is disposed on the base member 12. In the first embodiment, the semiconductor device 10 includes a resin package 18 disposed on the base member 12. Pressure measured by the semiconductor device 10 includes, for example, absolute pressure, gauge pressure, differential pressure, and atmospheric pressure. The top view in FIG. 2 and top views in FIG. 7 and FIG. 9 described later do not illustrate the protective film 15.

As illustrated in FIG. 2, FIG. 3A, and FIG. 3B, the base member 12 is a circuit board having a first main surface 12a, and formed from, for example, a ceramic board or a resin board. The base member 12 may be a lead frame. On the first main surface 12a of the base member 12, the detecting element 14 and the circuit element 16 are arranged side by side. In the first embodiment, the detecting element 14 and the circuit element 16 are fixed onto the first main surface 12a of the base member 12 with an adhesive material not illustrated. As the adhesive material, a die-attach film or a die-bond material is used.

As illustrated in FIG. 2 and FIG. 3A, at the first main surface 12a of the base member 12, connection terminals 12b that are electrically connected to the detecting element 14 with bonding wires 20, and connection terminals 12c that are electrically connected to the circuit element 16 with bonding wires 22 are disposed.

As illustrated in FIG. 3A and FIG. 3B, the base member 12 has a second main surface 12d opposite to the first main surface 12a, and includes an external connection terminal 12e on the second main surface 12d to be electrically connected to an external electronic device (not illustrated).

In the first embodiment, the detecting element 14 is a pressure sensor element for measuring pressure. The detecting element 14 is, for example, a piezoresistive pressure sensor element or a capacitive pressure sensor element, and is a micro-electromechanical system (MEMS) device.

As illustrated in FIG. 3A, the detecting element 14 has a first main surface 141, a second main surface 142 opposite to the first main surface 141, and side surfaces 143. The side surfaces 143 connect the first main surface 141 and the second main surface 142 to each other. The first main surface 141 is an example of a first surface.

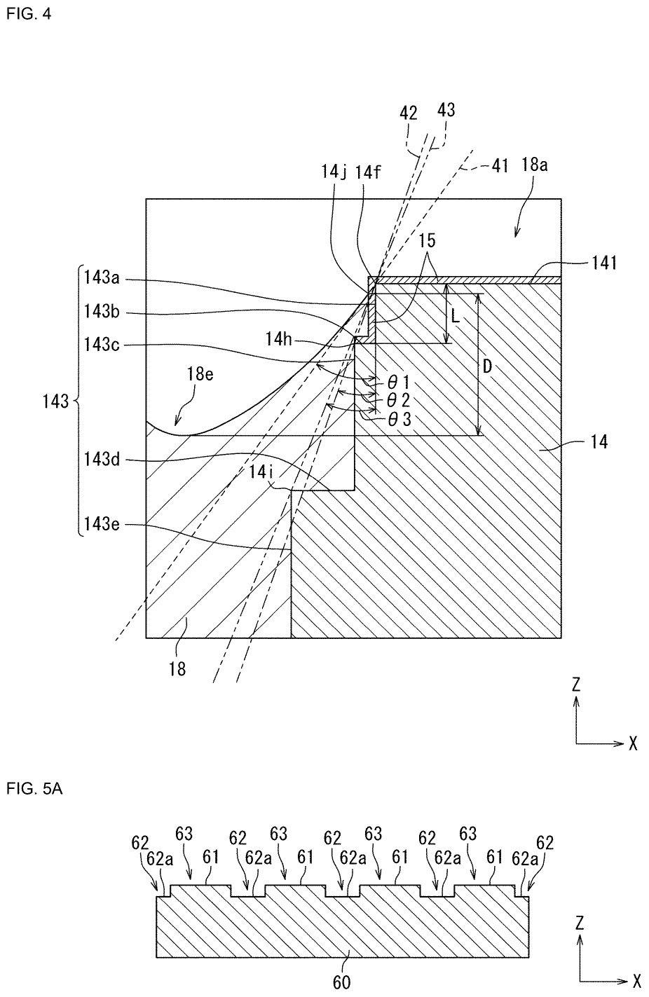

FIG. 4 is an enlarged view of a portion enclosed by a broken line in FIG. 3B. As illustrated in FIG. 4, the side surfaces 143 include a first side surface 143a, a second side surface 143b, a third side surface 143c, a fourth side surface 143d, and a fifth side surface 143e.

The first side surface 143a extends from an outer periphery 14f of the first main surface 141 of the detecting element 14 toward the base member 12. In the first embodiment, the first side surface 143a extends in a Z direction orthogonal to the first main surface 141, but may instead extend in a direction inclined with respect to the Z direction. The first side surface 143a is an example of a second surface. The Z direction is an example of an orthogonal direction.

The second side surface 143b extends outward from the first side surface 143a when viewed from above (when viewed in a Z-axis direction), and faces in the Z direction. In the first embodiment, the second side surface 143b extends from an end portion of the first side surface 143a opposite to the end portion located closer to the outer periphery 14f in the Z direction. In the first embodiment, the second side surface 143b extends along a virtual plane (a virtual plane orthogonal to the Z direction) extending in an X direction and a Y direction, but may instead extend in a direction inclined with respect to the virtual plane. The second side surface 143b is an example of a third surface.

The third side surface 143c extends from the second side surface 143b toward the base member 12. In the first embodiment, the third side surface 143c extends from an outer periphery 14h of the second side surface 143b when viewed from above. In the first embodiment, the third side surface 143c extends in the Z direction, but may instead extend in a direction inclined with respect to the Z direction. The third side surface 143c is an example of a fourth surface.

The fourth side surface 143d extends outward from the third side surface 143c when viewed from above, and faces in the Z direction. In the first embodiment, the fourth side surface 143d extends from an end portion of the third side surface 143c opposite to the outer periphery 14h of the second side surface 143b in the Z direction. In the first embodiment, the fourth side surface 143d extends along the virtual plane extending in the X direction and the Y direction, but may instead extend in a direction inclined with respect to the virtual plane. The fourth side surface 143d is an example of a fifth surface.

The fifth side surface 143e extends from the fourth side surface 143d toward the base member 12. In the first embodiment, the fifth side surface 143e extends from an outer periphery 14i of the fourth side surface 143d when viewed from above. In the first embodiment, the fifth side surface 143e extends in the Z direction, but may instead extend in a direction inclined with respect to the Z direction. The fifth side surface 143e is an example of a sixth surface.

Of the side surfaces 143 with the above structure, the second side surface 143b serves as a step between the first side surface 143a and the third side surface 143c. In addition, the fourth side surface 143d serves as a step between the third side surface 143c and the fifth side surface 143e.

As illustrated in FIG. 2, the detecting element 14 includes, on the first main surface 141, multiple connection terminals 14c electrically connected to the connection terminals 12b of the base member 12 with the bonding wires 20. Thus, the detecting element 14 is electrically connected to the circuit element 16 with the base member 12 (with a conductor pattern (not illustrated) disposed at the board).

As illustrated in FIG. 2, FIG. 3A, and FIG. 3B, the detecting element 14 includes a detector 14d, on which pressure is exerted, at the first main surface 141. In the first embodiment, the detector 14d of the detecting element 14 serving as a pressure sensor element is a membrane or a diaphragm that receives pressure.

As illustrated in FIG. 2 and FIG. 3A, the detecting element 14 includes a groove 14e on the first main surface 141 at a portion between the multiple connection terminals 14c and the detector 14d, although the reason for this is described later.

The protective film 15 illustrated in FIG. 3A, FIG. 3B, and FIG. 4 is, for example, a passivation film. The protective film 15 contains, for example, silicon nitride (SiN), and has insulating properties. The protective film 15 is provided to reduce, for example, water or dust adhering to the detecting element 14, or particularly, adhering to the detector 14d of the detecting element 14.

As illustrated in FIG. 3A, FIG. 3B, and FIG. 4, the protective film 15 covers the detector 14d, the first main surface 141, the first side surface 143a, and the second side surface 143b of the detecting element 14. More specifically, the detector 14d, the first main surface 141, the first side surface 143a, and the second side surface 143b are waterproofed by the protective film 15.

In the first embodiment, as illustrated in FIG. 3B, the circuit element 16 has a first main surface 16a and a second main surface 16b opposite to the first main surface 16a. The circuit element 16 is an element including an application specific integrated circuit (ASIC). In the first embodiment, the circuit element 16 is disposed on the first main surface 12a of the base member 12 with the second main surface 16b facing the first main surface 12a.

As illustrated in FIG. 2, the circuit element 16 includes multiple connection terminals 16c disposed on the first main surface 16a, and electrically connected to the connection terminals 12c of the base member 12 with bonding wires 22. The circuit element 16 is thus electrically connected to the detecting element 14 with the base member 12 (with a conductor pattern (not illustrated) disposed on the board).

The circuit element 16 is an element that includes a signal processing circuit. The signal processing circuit processes signals output from the detecting element 14, and outputs the processed signals to the base member 12. For example, in the first embodiment, the circuit element 16 includes a converter that converts voltage signals output from the detecting element 14 to digital signals, a filter that filters the digital signals from the converter, a temperature sensor that detects the temperature, a processor that corrects the digital signals filtered based on the temperature detected by the temperature sensor, and a memory that stores a correction coefficient used to correct the digital signals using the detected temperature.

In the first embodiment, the resin package 18 illustrated in FIG. 1 to FIG. 4 is a package formed by shaping a hard resin such as a thermosetting resin on the first main surface 12a of the base member 12. The method for forming the resin package 18 is described in detail later.

A portion of the first main surface 12a of the base member 12 including the multiple connection terminals 12b and 12c is covered with the resin package 18 to be protected and waterproofed. The detecting element 14 (particularly, the connection terminals 14c), the circuit element 16 (particularly, the connection terminal 16c), and the bonding wires 20 and 22 that electrically connect these elements to each other are embedded in the resin package 18 to be protected and waterproofed. More specifically, the resin package 18 protects electric connection between the base member 12 and the detecting element 14 and electric connection between the base member 12 and the circuit element 16.

As illustrated in FIG. 1, FIG. 3A, and FIG. 3B, to allow pressure to be exerted on the detector 14d of the detecting element 14 with the protective film 15 interposed therebetween, the resin package 18 includes an exposure hole 18a to allow the detector 14d of the detecting element 14 to be exposed to the outside of the resin package 18 with the protective film 15 interposed therebetween.

More specifically, in the first embodiment, as illustrated in FIG. 1, the resin package 18 includes a rectangular parallelepiped body portion 18b disposed on the base member 12, and a cylindrical ring-shaped holding portion 18c disposed on the body portion 18b. The exposure hole 18a is open in a top surface 18d of the ring-shaped holding portion 18c, and extends toward the first main surface 12a of the base member 12. Pressure is exerted on, with the protective film 15 interposed therebetween, the detector 14d of the detecting element 14 exposed through the exposure hole 18a to the outside of the resin package 18 with the protective film 15 interposed therebetween, and the semiconductor device 10 can measure the pressure.

The ring-shaped holding portion 18c of the resin package 18 is used to hold an O-ring (not illustrated) on its outer peripheral surface. For example, the ring-shaped holding portion 18c of the resin package 18 of the semiconductor device 10 is inserted, with the O-ring interposed therebetween, into a through-hole that connects the outside and the internal space in the housing of an electronic device to which the semiconductor device 10 is attached. More specifically, in the first embodiment, the resin package 18 also has a function of attaching the semiconductor device 10 to an electronic device.

As illustrated in FIG. 2, to allow at least a portion of the outer periphery 14f of the first main surface 141 of the detecting element 14 to be exposed through the exposure hole 18a of the resin package 18, the resin package 18 includes a recess 18e extending along the exposed portion of the outer periphery 14f. More specifically, the portion of the resin package 18 disposed on the first main surface 141 of the detecting element 14 is kept to a minimum. The reason why the resin package 18 is disposed in this manner is described later.

More specifically, in the first embodiment, the outer periphery 14f of the first main surface 141 of the detecting element 14 has a shape of a rectangle with four sides when viewed from above. One side 14g of the outer periphery 14f along which the multiple connection terminals 14c connected to the bonding wires 20 are arranged adjacent to each other is embedded in the resin package 18 together with the connection terminals 14c and the bonding wires 20. Other sides of the outer periphery 14f other than the side 14g are exposed to the outside of the resin package 18. The resin package 18 includes the recess 18e extending along the sides of the outer periphery 14f other than the side 14g.

The recess 18e has a bottom portion shaped to be located closer to the base member 12 than the first main surface 141 of the detecting element 14.

As illustrated in FIG. 4, a depth D of the recess 18e in the Z direction is longer than a length L of the first side surface 143a in the Z direction. In the first embodiment, the depth D of the recess 18e is, for example, approximately 10 μm. In the first embodiment, the length L of the first side surface 143a is larger than or equal to 1 μm and smaller than or equal to 10 μm. The depth D of the recess 18e may be smaller than or equal to the length L of the first side surface 143a. Alternatively, the depth D of the recess 18e and the length L of the first side surface 143a are not limited to the above numerical values and the above numerical ranges.

The reason why the length L of the first side surface 143a is set to be larger than or equal to 1 μm is because the portion of the first side surface 143a is left without being covered with the resin package 18 by approximately 1 μm during the manufacturing process of the semiconductor device 10. Here, the portion of the first side surface 143a left without being covered with the resin package 18 is a portion of the first side surface 143a located closer to the first main surface 141 in the Z direction than a boundary 14j in FIG. 4.

The reason why the length L of the first side surface 143a is set to be smaller than or equal to 10 μm is as follows. If the length L is larger than 10 μm, the protective film 15 is more likely to fail to be formed over the entirety of the first side surface 143a during the manufacturing process of the detecting element 14, and the third side surface 143c and the fourth side surface 143d are more likely to fail to be formed by forming second grooves 64 in a second groove forming process described later.

As illustrated in FIG. 4, when viewed in a direction along the first main surface 141, in other words, when viewed in a direction along the XY plane, an inclination angle θ1 is larger than an inclination angle θ2. The inclination angle θ1 is an angle of a virtual tangent 41 with respect to the first side surface 143a. The virtual tangent 41 is a tangent to the surface of the recess 18e at the boundary 14j between the recess 18e and the protective film 15 covering the first side surface 143a. The inclination angle θ2 is an angle of a virtual line 42 with respect to the first side surface 143a. The virtual line 42 is a line passing the outer periphery 14f, which is a boundary between the first main surface 141 and the first side surface 143a, and the outer periphery 14h, which is a boundary between the second side surface 143b and the third side surface 143c.

When viewed in a direction along the XY plane, the inclination angle θ1 is larger than an inclination angle θ3. The inclination angle θ3 is an angle of a virtual line 43 with respect to the first side surface 143a. The virtual line 43 is a line passing the outer periphery 14f, which is a boundary between the first main surface 141 and the first side surface 143a, and the outer periphery 14i, which is a boundary between the fourth side surface 143d and the fifth side surface 143e.

In the first embodiment, the inclination angle θ1 is larger than or equal to 35 degrees, but may instead be smaller than 35 degrees.

In the first embodiment, the direction along the first main surface 141 (the direction along the XY plane) is any direction along the first main surface 141. More specifically, the relationship between the inclination angles θ1, θ2, and θ3 described above is satisfied regardless of when viewed in any direction along the first main surface 141. The relationship between the inclination angles θ1, θ2, and θ3 described above may be satisfied only when viewed in one or more of the directions along the first main surface 141. Alternatively, the relationship between the inclination angles θ1, θ2, and θ3 described above may fail to be satisfied regardless of any direction along the first main surface 141.

In the resin package 18 with the above structure, the multiple connection terminals 14c and portions around the connection terminals 14c at the first main surface 141 of the detecting element 14 are embedded in the resin package 18.

When the resin package 18 is adjacent to the outer periphery 14f of the first main surface 141 (more specifically, the protective film 15 covering the outer periphery 14f), the resin package 18 completely covers the first side surface 143a.

However, when the resin package 18 is adjacent to the first side surface 143a (more specifically, the protective film 15 covering the first side surface 143a) at a position closer to the base member 12 than the outer periphery 14f of the first main surface 141, the resin package 18 fails to cover at least a portion of the first side surface 143a. More specifically, in the semiconductor device 10, the resin package 18 does not cover at least a portion of the first side surface 143a. In this structure, the first side surface 143a can be exposed through the exposure hole 18a. However, the first side surface 143a is covered with the protective film 15, and the first side surface 143a is thus protected from adhesion of, for example, water or dust. In the first embodiment, the resin package 18 does not cover a portion of the first side surface 143a (more specifically, a portion of the first side surface 143a located closer to the first main surface 141 in the Z direction from the boundary 14j).

When the resin package 18 is adjacent to the second side surface 143b (more specifically, the protective film 15 covering the second side surface 143b), the resin package 18 does not cover the entirety of the first side surface 143a and at least a portion of the second side surface 143b. More specifically, the semiconductor device 10 has a structure where the resin package 18 does not cover the entirety of the first side surface 143a and at least a portion of the second side surface 143b. In this case, the first side surface 143a and the second side surface 143b can be exposed through the exposure hole 18a. However, the first side surface 143a and the second side surface 143b are covered with the protective film 15, and the first side surface 143a is thus protected from adhesion of, for example, water or dust. In the first embodiment, the resin package 18 covers the entirety of the second side surface 143b.

As described above, the resin package 18 covers the detecting element 14 with a portion excluding the exposure hole 18a. The portion excluding the exposure hole 18a corresponds to the first main surface 141 and the detector 14d. However, depending on the structure of the resin package 18, the portion excluding the exposure hole 18a can include, in addition to the first main surface 141 and the detector 14d, at least one of the first side surface 143a and the second side surface 143b.

Subsequently, a method for manufacturing the semiconductor device 10 with the above structure, particularly, a method for manufacturing the detecting element 14 and the resin package 18 is described.

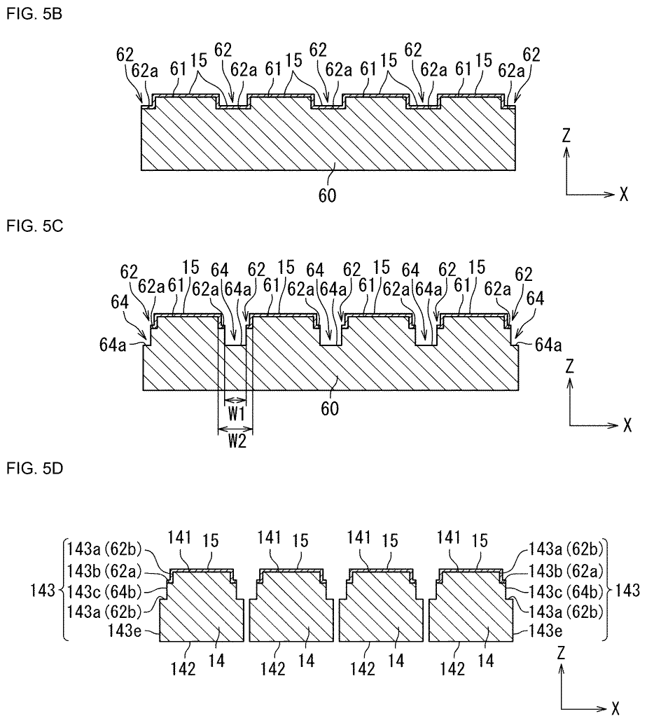

FIG. 5A to FIG. 5D each illustrate one process of manufacturing a detecting element in the method for manufacturing the semiconductor device 10. In FIG. 5A to FIG. 5D, the detector 14d is not illustrated.

First, a base portion 60 (refer to FIG. 5A to FIG. 5D) is prepared. The base portion 60 serves as a base of the detecting element 14 formed from a MEMS device.

As illustrated in FIG. 5A, a first groove forming process for forming first grooves 62 in a main surface 61 of the base portion 60 is performed. Thus, the main surface 61 is divided into multiple areas 63 with the first grooves 62 in a plan view of the base portion 60 in which the main surface 61 is viewed in a direction orthogonal to the main surface 61, more specifically, when viewed from above (when viewed in the Z-axis direction). In the first embodiment, the main surface 61 is divided into the multiple areas 63 arrayed in the X direction and the Y direction, and each area 63 is rectangular. In the first groove forming process, the groove 14e (refer to FIG. 2 and FIG. 3A) may be formed in each area 63 of the main surface 61 of the base portion 60 between the first groove forming process and a protective film forming process described below.

Subsequently, as illustrated in FIG. 5B, a protective film forming process for forming the insulating protective film 15 on the main surface 61 is performed. The main surface 61 includes the first grooves 62 formed in the first groove forming process. Thus, the main surface 61 including the first grooves 62 is covered with the protective film 15.

Subsequently, as illustrated in FIG. 5C, a second groove forming process for forming the second grooves 64 along bottom surfaces 62a of the first grooves 62 is performed. A width W1 of a bottom surface 64a of each second groove 64 is smaller than a width W2 of the bottom surface 62a of each first groove 62. Thus, a step is formed between each first groove 62 and the corresponding second groove 64 by the difference between the two widths W1 and W2.

Subsequently, as illustrated in FIG. 5D, a cutting process for cutting the base portion 60 covered with the protective film 15 along the first grooves 62 and the second grooves 64 is performed. In the first embodiment, the base portion 60 is cut in the Z direction from the bottom surfaces 64a of the second grooves 64. Thus, the base portion 60 is divided into multiple detecting elements 14. In the first embodiment, a blade (not illustrated) for cutting the base portion 60 has a width smaller than the width W2 of the bottom surfaces 64a of the second grooves 64.

In each of the multiple detecting elements 14 divided in the cutting process, the portion corresponding to a side surface 62b of each first groove 62 serves as the first side surface 143a. The portion corresponding to the bottom surface 64a of each first groove 62 serves as the second side surface 143b. The portion corresponding to the side surface 64b of each second groove 64 serves as the third side surface 143c. The portion corresponding to the bottom surface 64a of each second groove 64 serves as the fourth side surface 143d. A cut surface exposed after the base portion 60 is cut in the cutting process serves as the fifth side surface 143e.

The manufacture of the base portion 60 and the above processes are performed with a known fine-processing technology (for example, a technology for manufacturing a semiconductor integrated circuit). For example, when the base portion 60 includes multiple layers, the first grooves 62 and the second grooves 64 are formed by, for example, etching during a process of laminating layers of the base portion 60. In this case, in the process of laminating layers of the base portion 60, the first grooves 62 may be formed after the second grooves 64 are formed.

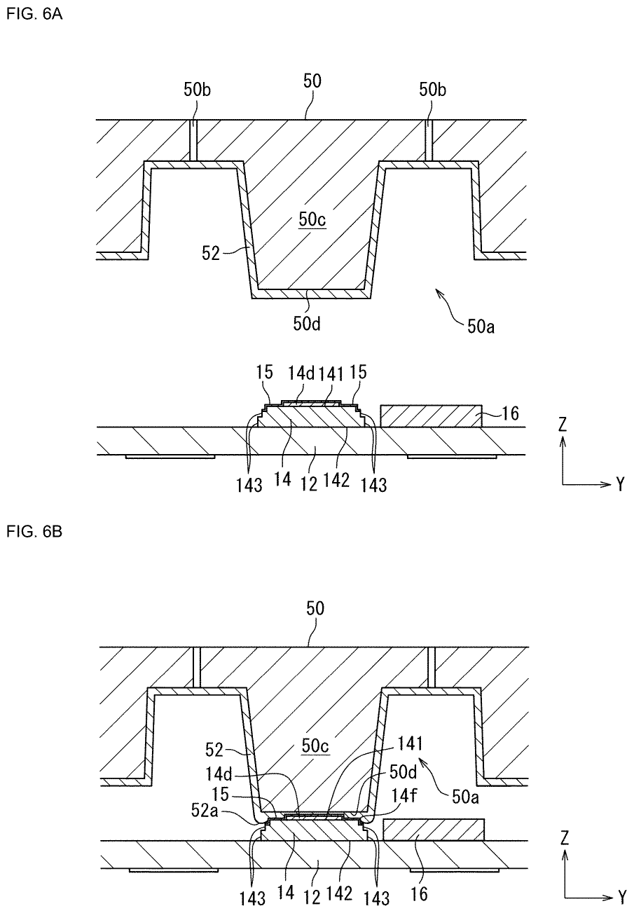

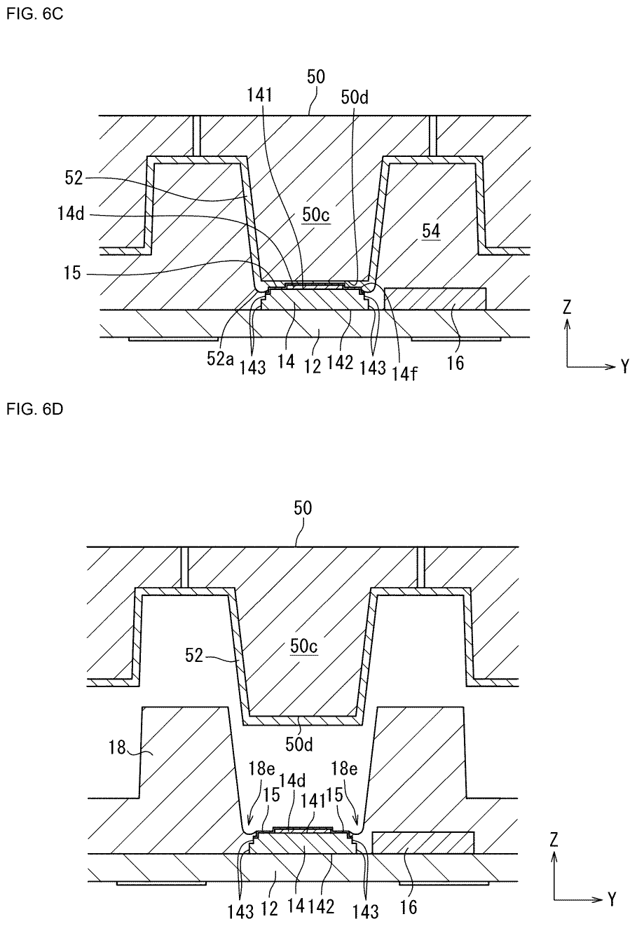

FIG. 6A to FIG. 6D each illustrate a process of manufacturing a resin package in a method for manufacturing the semiconductor device 10.

As illustrated in FIG. 6A, the detecting element 14 formed in the above manner and the circuit element 16 are disposed on the base member 12. More specifically, the detecting element 14 and the circuit element 16 are mounted on the base member 12.

The base member 12 at which the bonding wires 20 and 22 are disposed is then placed in a predetermined position with respect to a die 50. The die 50 includes a cavity 50a for forming the resin package 18 and suction holes 50b for sucking air in the cavity 50a. The cavity 50a also includes a protrusion 50c for forming the exposure hole 18a of the resin package 18. The protrusion 50c has a flat top surface 50d.

Before the die 50 is filled with the resin material of the resin package 18, a release film 52 is sucked through the suction holes 50b to come into close contact with the surface of the cavity 50a. The release film 52 is, for example, a heat-resistant resin film having a surface coated with a release agent.

As illustrated in FIG. 6B, the die 50 in which the release film 52 is in close contact with the surface of the cavity 50a moves toward the base member 12, and the top surface 50d of the protrusion 50c of the die 50 comes into contact with the detecting element 14 on the base member 12 with the release film 52 interposed therebetween. Thus, the die 50 is placed with respect to the base member 12 while the first main surface 141 of the detecting element 14 is thrust into a portion of the release film 52 on the top surface 50d of the protrusion 50c.

FIG. 7 is a top view of a semiconductor device illustrating the positional relationship between the die and the detecting element.

As illustrated in FIG. 7, in the first embodiment, the top surface 50d of the protrusion 50c of the die 50 is rectangular, and has an outer periphery 50e. As illustrated in FIG. 6B, when the top surface 50d of the protrusion 50c of the die 50 is in contact with the detecting element 14 with the release film 52 interposed therebetween, at least a portion of the outer periphery 50e of the top surface 50d is located outward from the outer periphery 14f of the first main surface 141 when viewed in a direction in which the protrusion 50c and the first main surface 141 of the detecting element 14 face each other (when viewed in the Z-axis direction).

In the first embodiment, as illustrated in FIG. 7, a portion of the outer periphery 50e of the top surface 50d of the protrusion 50c of the die 50 is located outward from a portion of the outer periphery 14f of the first main surface 141 of the detecting element 14 excluding the side 14g along which the multiple connection terminals 14c are arranged. More specifically, a portion near the side 14g and the connection terminals 14c does not face the top surface 50d of the protrusion 50c of the die 50.

With the positional and dimensional relationships between the top surface 50d of the protrusion 50c of the die 50 and the first main surface 141 of the detecting element 14, as illustrated in FIG. 6B, a wall-shaped portion 52a of the release film 52 that protrudes toward the base member 12 beyond the first main surface 141 and surrounds a portion of the outer periphery 14f of the first main surface 141 is formed.

As illustrated in FIG. 6C, the cavity 50a of the die 50 is filled with a molten resin material 54. At this time, the wall-shaped portion 52a of the release film 52 blocks the resin material 54 that is to enter a space between the release film 52 and the first main surface 141 of the detecting element 14. This structure thus reduces the resin material 54 that covers the detector 14d of the detecting element 14.

However, in the first embodiment, as illustrated in FIG. 8, the wall-shaped portion 52a of the release film 52 is not located at the side 14g of the outer periphery 14f of the first main surface 141 of the detecting element 14. Thus, the resin material 54 may enter a space between the release film 52 and the first main surface 141 of the detecting element 14 around the side 14g.

To address this, the first embodiment includes the groove 14e disposed near a portion between the detector 14d and the multiple connection terminals 14c on the first main surface 141 of the detecting element 14. When the resin material 54 is to move from the side 14g toward a space between the release film 52 and the first main surface 141 of the detecting element 14, the moving resin material 54 flows into the groove 14e before reaching the detector 14d. This structure thus reduces the moving resin material 54 that reaches the detector 14d of the detecting element 14 and that covers at least a portion of the detector 14d.

When the multiple connection terminals 14c and the detector 14d are spaced a sufficiently large distance from one another, more specifically, when the multiple connection terminals 14c and the detector 14d are spaced a distance that does not allow the moving resin material 54 to reach the detector 14d, the groove 14e may be eliminated.

As illustrated in FIG. 6C, after the cavity 50a of the die 50 is filled with the resin material 54 and then the resin material 54 cures, as illustrated in FIG. 6D, the die 50 and the release film 52 are detached from the cured resin material 54. The resin package 18 including the recess 18e having a shape corresponding to the wall-shaped portion 52a of the release film 52 illustrated in FIG. 6C and following a part of the outer periphery 14f of the first main surface 141 of the detecting element 14 is thus formed on the base member 12.

According to the first embodiment described above, the semiconductor device 10 including the detecting element 14 including the detector 14d and the resin package 18 including the exposure hole 18a that allows the detector 14d to be exposed to the outside can reduce degradation of detection performance of the detecting element 14 due to the resin package 18.

More specifically, as illustrated in FIG. 2, to allow at least a portion of the outer periphery 14f of the first main surface 141 of the detecting element 14 to be exposed through the exposure hole 18a, the resin package 18 includes the recess 18e extending along the exposed outer periphery 14f. Thus, first, the resin material 54 of the resin package 18 is prevented from covering the detector 14d of the detecting element 14 during manufacture of the semiconductor device 10. This structure thus reduces degradation of detection performance of the detecting element 14 due to the resin package 18.

Thus, a portion of the resin package 18 disposed on the first main surface 141 of the detecting element 14 is kept to a minimum. This structure thus reduces degradation of detection performance of the detecting element 14.

More specifically, during use of the semiconductor device 10, the resin package 18 may receive an external force. For example, in the first embodiment, the resin package 18 receives compressive force from an O-ring held by the ring-shaped holding portion 18c of the resin package 18. The external force acts on the detecting element 14 with the resin package 18 interposed therebetween. Particularly, when a portion of the resin package 18 is disposed on the first main surface 141 of the detecting element 14, the first main surface 141 may receive distortion with the resin package 18 interposed therebetween. Thus, the detector 14d disposed on the first main surface 141 may be deformed, and the detection performance of the detecting element 14 may be degraded.

Thus, to allow at least a portion of the outer periphery 14f of the first main surface 141 of the detecting element 14 to be exposed through the exposure hole 18a, the resin package 18 includes the recess 18e extending along the exposed outer periphery 14f. This structure reduces occurrence of distortion in the first main surface 141 of the detecting element 14 (compared to the structure where the entirety of the outer periphery 14f is embedded in the resin package 18 and the recess 18e is thus not formed in the resin package 18). This structure thus reduces degradation of the detection performance of the detecting element 14 due to the resin package 18.

In the first embodiment, the recess 18e is formed along the outer periphery 14f. Thus, compared to the second side surface 143b and the third side surface 143c, the first side surface 143a located near the outer periphery 14f is more likely to be exposed by the recess 18e without being covered with the resin package 18. In the first embodiment, the protective film 15 covers the first side surface 143a in addition to the first main surface 141. More specifically, in the first embodiment, the first side surface 143a that is highly likely to be exposed is covered with the protective film 15. This structure can thus reduce the likelihood of the first side surface 143a coming into contact with water. This structure can thus reduce degradation of waterproofness of the detecting element 14.

In the first embodiment, the protective film 15 covers the second side surface 143b in addition to the first main surface 141 and the first side surface 143a. This structure can thus reduce the likelihood of the second side surface 143b coming into contact with water. This structure can thus reduce degradation of waterproofness of the detecting element 14 compared to a structure in which the second side surface 143b is not covered with the protective film 15.

When the length L of the first side surface 143a in the Z direction is excessively long, the protective film 15 may fail to be formed over the entirety of the first side surface 143a in the manufacturing process of the semiconductor device 10. In the first embodiment, the length L of the first side surface 143a in the Z direction is shorter than the depth D of the recess 18e in the Z direction. Thus, compared to a structure where the length L is larger than or equal to the depth D, in this structure, the protective film 15 is less likely to fail to be formed over the entirety of the first side surface 143a.

In the first embodiment, the inclination angle θ1 is larger than the inclination angle θ2. Thus, the surface defining the recess 18e of the resin package 18, which covers the first side surface 143a, the second side surface 143b, and the third side surface 143c, that is, the surface of the resin package 18 is spaced farther apart from the first side surface 143a, the second side surface 143b, and the third side surface 143c as it extends toward the base member 12. Thus, the first side surface 143a, the second side surface 143b, and the third side surface 143c are less likely to be exposed through the surface defining the recess 18e of the resin package 18 (the surface of the resin package 18).

In the first embodiment, to manufacture, by cutting the base portion 60 on which the protective film 15 is disposed, the multiple detecting elements 14 on each of which the protective film 15 is disposed, the cutting is started at the fourth side surface 143d to form the fifth side surface 143e as a cut surface. Thus, regardless of when the detecting element 14 is chipped at the fourth side surface 143d or the fifth side surface 143e, the first side surface 143a is less likely to be affected by the chipping. Thus, during the cutting, the protective film 15 disposed on the first side surface 143a is less likely to be broken.

In the first embodiment, the inclination angle θ1 is larger than the inclination angle θ3. Thus, the surface defining the recess 18e of the resin package 18, which covers the fourth side surface 143d and the fifth side surface 143e, that is, the surface of the resin package 18 is spaced farther apart from the fourth side surface 143d and the fifth side surface 143e as it extends toward the base member 12. Thus, the fourth side surface 143d and the fifth side surface 143e are less likely to be exposed through the surface defining the recess 18e of the resin package 18 (the surface of the resin package 18).

With this manufacturing method, when the base portion 60 is cut and divided into the multiple detecting elements 14, the side surface of each first groove 62 covered with the protective film 15 serves as the first side surface 143a, and the bottom surface of each first groove 62 covered with the protective film 15 serves as the second side surface 143b. In this manner, the semiconductor device 10 including the detecting element 14 in which, in addition to the first main surface 141, the first side surface 143a and the second side surface 143b are covered with the protective film 15 can be easily manufactured.

With this manufacturing method, regardless of when the base portion 60 is chipped while the base portion 60 is cut along the second grooves 64, the first grooves 62 different from the second grooves 64 are less likely to be affected by the chipping. Thus, the protective film covering the first grooves 62 is less likely to be broken by chipping.

### Second Embodiment

As illustrated in FIG. 2, in the first embodiment, a portion (the side 14g) of the outer periphery 14f of the first main surface 141 of the detecting element 14 is embedded in the resin package 18. Thus, the recess 18e of the resin package 18 is not located throughout the entire outer periphery 14f of the first main surface 141 of the detecting element 14. Unlike this structure, in the second embodiment, the recess of the resin package is located throughout the entire outer periphery of the first surface of the detecting element. A semiconductor device according to the second embodiment is described mainly in terms of this different point.

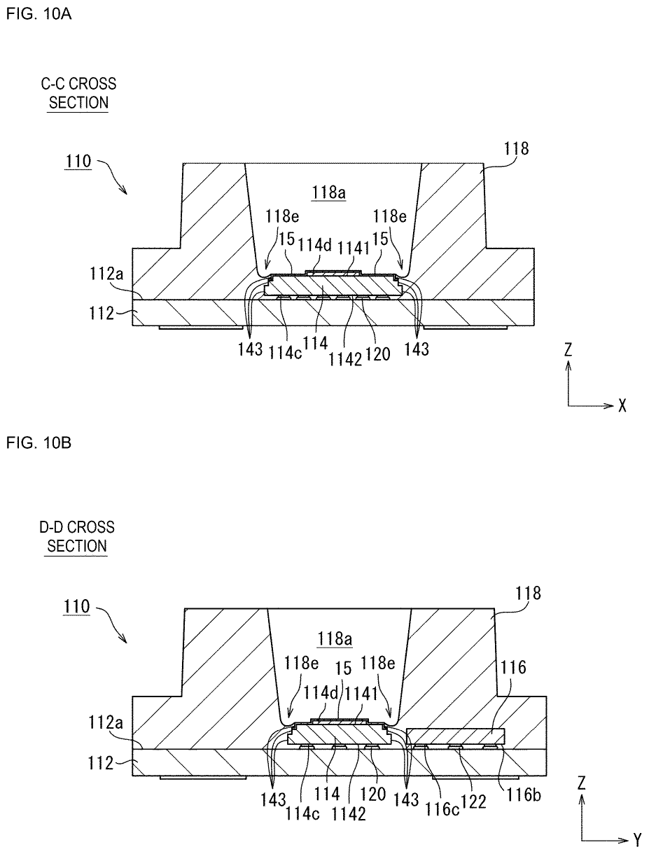

FIG. 9 is a top view of a semiconductor device according to the second embodiment. FIG. 10A and FIG. 10B are cross-sectional views of the semiconductor device according to the second embodiment taken along line C-C and line D-D in FIG. 9.

As illustrated in FIG. 9, FIG. 10A, and FIG. 10B, in a semiconductor device 110 according to the second embodiment, a detecting element 114 includes multiple connection terminals 114c disposed not at a first surface 1141 on which a detector 114d is disposed, but at a second surface 1142 opposite to the first surface 1141. The detecting element 114 has side surfaces 1143. The side surfaces 1143 correspond to the side surfaces 143 of the detecting element 14 according to the first embodiment.

The detecting element 114 is placed on a base member 112 with the second surface 1142 facing the base member 112. The multiple connection terminals 114c on the second surface 1142 are electrically connected to the base member 112 (the conductor pattern on a first surface 112a) with solder 120.

In the detecting element 114 with this structure, no connection terminal is disposed at the first surface 1141, and a resin package 118 has no need of covering the first surface 1141 of the detecting element 114. Thus, as illustrated in FIG. 9, to expose the entirety of an outer periphery 114f of the first surface 1141 of the detecting element 114 through an exposure hole 118a, the resin package 118 includes an annular recess 118e extending along the exposed outer periphery 114f.

In the second embodiment, a circuit element 116 also includes multiple connection terminals 116c disposed at a second surface 116b facing the base member 112. The multiple connection terminals 116c are electrically connected to the base member 112 with solder 122.

As in the case of the first embodiment described above, the semiconductor device 110 according to the second embodiment including the detecting element 114 including the detector 114d and the resin package 118 having the exposure hole 118a through which the detector 114d is exposed to the outside can also reduce degradation of detection performance of the detecting element 114 due to the resin package 118.

Although the present disclosure has been described using multiple embodiments, embodiments of the present disclosure are not limited to these.

For example, in the first embodiment described above, as illustrated in FIG. 2 and FIG. 3B, the detecting element 14 and the circuit element 16 are mounted on the base member 12 while being arranged side by side. However, embodiments of the present disclosure are not limited to this example.

For example, the circuit element may be mounted on the base member, and the detecting element may be mounted on the circuit element. More specifically, the detecting element is indirectly disposed on the base member with the circuit element interposed therebetween. In this case, for example, the detecting element may be electrically connected to the circuit element with bonding wires or solder.

Alternatively, the detecting element and the circuit element may be integrated. For example, a circuit in the circuit element may be incorporated in the detecting element.

In the first embodiment described above, the semiconductor device 10 is a so-called pressure sensor that measures pressure. However, embodiments of the present disclosure are not limited to this example. For example, a semiconductor device according to an embodiment of the present disclosure may be a sensor that detects (measures), for example, light, ultrasonic waves, or a specific gas, or may be a microphone. More specifically, a semiconductor device according to an embodiment of the present disclosure includes a detecting element that includes a detector, which is exposed to the outside of the semiconductor device to be capable of detecting a detection target. For example, when the semiconductor device is an optical sensor that detects light, the optical sensor includes a photodiode as the detecting element. Alternatively, for example, when the semiconductor device is an ultrasonic wave sensor that detects ultrasonic waves, the ultrasonic wave sensor includes an ultrasonic transducer as the detecting element.

The semiconductor device described above can be expressed in the following manner.

A semiconductor device according to a first aspect, comprising: a base member; a detecting element on the base member and having a first surface with a detector; an insulating protective film that covers the detector and the first surface; and a resin package on the base member and including an exposure hole that exposes the detector of the detecting element to an outside with the protective film interposed therebetween, a portion of the resin package excluding the exposure hole covering the detecting element such that at least a portion of an outer periphery of the first surface is exposed through the exposure hole, and the resin package includes a recess extending along the portion of the outer periphery exposed through the exposure hole, wherein the detecting element further has: a second surface extending from the outer periphery toward the base member, a third surface extending outward from the second surface when viewed in a direction orthogonal to the first surface, and a fourth surface extending from the third surface toward the base member, and wherein the protective film covers the second surface.

A semiconductor device according to a second aspect is the semiconductor device according to the first aspect, wherein the protective film further covers the third surface.

A semiconductor device according to a third aspect is the semiconductor device according to the first or second aspect, wherein a length of the second surface in the direction orthogonal to the first surface is shorter than a depth of the recess in the direction orthogonal to the first surface.

A semiconductor device according to a fourth aspect is the semiconductor device according to any one of the first to third aspects, wherein, when viewed in a direction along the first surface, a first inclination angle of a virtual tangent to a surface of the recess at a first boundary between the recess and the protective film that covers the second surface with respect to the second surface is larger than a second inclination angle of a first virtual line passing a second boundary between the first surface and the second surface and a third boundary between the third surface and the fourth surface with respect to the second surface.

A semiconductor device according to a fifth aspect is the semiconductor device according to any one of the first to fourth aspects, wherein the detecting element further has a fifth surface extending outward from the fourth surface when viewed in the direction orthogonal to the first surface, and a sixth surface extending from the fifth surface toward the base member.

A semiconductor device according to a sixth aspect is the semiconductor device according to the fifth aspect, wherein, when viewed in a direction along the first surface, the first inclination angle of the virtual tangent to the surface of the recess at the first boundary between the recess and the protective film that covers the second surface with respect to the second surface is larger than a third inclination angle of a second virtual line passing the second boundary between the first surface and the second surface and a fourth boundary between the fifth surface and the sixth surface with respect to the second surface.

A method for manufacturing a semiconductor device according to a seventh aspect, the method comprising: forming a first groove in a main surface of a base portion to divide the main surface into a plurality of areas; covering the main surface including the first groove with an insulating protective film; cutting the base portion covered with the protective film along the first groove to divide the base portion into a plurality of detecting elements each having a first surface with a detector; placing each of the detecting elements on a base member; adhering a release film to a die having a cavity with a protrusion; placing the die with respect to the base member while the first surface of the detecting elements is thrust into a portion of the release film on a surface of the protrusion; filling the cavity of the die with a resin material; and detaching the die and the release film from a resin package formed from the resin material after curing, wherein at least a portion of an outer periphery of the surface of the protrusion is located outward from an outer periphery of the first surface when viewed in a direction in which the protrusion of the die and the first surface of the detecting element face each other.

A method for manufacturing a semiconductor device according to an eight aspect is the method for manufacturing a semiconductor device according to the seventh aspect, further comprising: after covering the main surface with the protective film and before cutting the base portion, forming a second groove with a smaller width than a bottom surface of the first groove along the bottom surface; and cutting the base portion covered with the protective film along the first groove and the second groove so as to divide the base portion into the plurality of detecting elements.

By combining any two or more of the various embodiments and modifications described above as appropriate, effects of each of the embodiments and modifications can be exerted.

The present disclosure is fully described in relation to preferred embodiments with reference to the drawings as appropriate, but various modifications and alterations are apparent to persons having ordinary skill in the art. Such modifications and alterations are to be understood to be included within the scope of the present disclosure as long as they do not depart from the scope defined by the appended claims.

### INDUSTRIAL APPLICABILITY

The present disclosure is applicable to a semiconductor device including a detecting element including a detector and a resin package that allows the detector to be exposed to the outside.

### REFERENCE SIGNS LIST

10 semiconductor device
12 base member
14 detecting element
141 first main surface (first surface)
143a first side surface (second surface)
143b second side surface (third surface)
143c third side surface (fourth surface)
143d fourth side surface (fifth surface)
143e fifth side surface (sixth surface)
14d detector
14f outer periphery (boundary)
14h outer periphery (boundary)
14i outer periphery (boundary)
14j boundary
15 protective film
18 resin package
18a exposure hole
18e recess
41 virtual tangent
42 virtual line
43 virtual line
50 die
50a cavity
50c protrusion
50d top surface
52 release film
54 resin material
60 base portion
61 main surface
62 first groove
62a bottom surface
63 area
64 second groove
D depth
L length
θ1 inclination angle
θ2 inclination angle
θ3 inclination angle

1. A semiconductor device, comprising:
a base member;
a detecting element on the base member and having a first surface with a detector;
an insulating protective film that covers the detector and the first surface; and
a resin package on the base member and including an exposure hole that exposes the detector of the detecting element to an outside with the protective film interposed therebetween, a portion of the resin package excluding the exposure hole covering the detecting element such that at least a portion of an outer periphery of the first surface is exposed through the exposure hole, and the resin package includes a recess extending along the portion of the outer periphery exposed through the exposure hole,
wherein the detecting element further has:
a second surface extending from the outer periphery toward the base member,
a third surface extending outward from the second surface when viewed in a direction orthogonal to the first surface, and
a fourth surface extending from the third surface toward the base member, and
wherein the protective film covers the second surface.

2. The semiconductor device according to claim 1, wherein the protective film further covers the third surface.

3. The semiconductor device according to claim 1, wherein a length of the second surface in the direction orthogonal to the first surface is shorter than a depth of the recess in the direction orthogonal to the first surface.

4. The semiconductor device according to claim 3, wherein the length of the second surface in the direction orthogonal to the first surface is 1 μm to 10 μm.

5. The semiconductor device according to claim 1, wherein, when viewed in a direction along the first surface, a first inclination angle of a virtual tangent to a surface of the recess at a first boundary between the recess and the protective film that covers the second surface with respect to the second surface is larger than a second inclination angle of a first virtual line passing a second boundary between the first surface and the second surface and a third boundary between the third surface and the fourth surface with respect to the second surface.

6. The semiconductor device according to claim 5, wherein the detecting element further has
a fifth surface extending outward from the fourth surface when viewed in the direction orthogonal to the first surface, and
a sixth surface extending from the fifth surface toward the base member.

7. The semiconductor device according to claim 6, wherein, when viewed in a direction along the first surface, the first inclination angle of the virtual tangent to the surface of the recess at the first boundary between the recess and the protective film that covers the second surface with respect to the second surface is larger than a third inclination angle of a second virtual line passing the second boundary between the first surface and the second surface and a fourth boundary between the fifth surface and the sixth surface with respect to the second surface.

8. The semiconductor device according to claim 7, wherein the first inclination angle is larger than or equal to 35 degrees.

9. The semiconductor device according to claim 4, wherein the first inclination angle is larger than or equal to 35 degrees.

10. The semiconductor device according to claim 1, wherein the detecting element further has
a fifth surface extending outward from the fourth surface when viewed in the direction orthogonal to the first surface, and
a sixth surface extending from the fifth surface toward the base member.

11. The semiconductor device according to claim 10, wherein, when viewed in a direction along the first surface, a first inclination angle of a virtual tangent to a surface of the recess at a first boundary between the recess and the protective film that covers the second surface with respect to the second surface is larger than a second inclination angle of a first virtual line passing a second boundary between the first surface and the second surface and a third boundary between the fifth surface and the sixth surface with respect to the second surface.

12. The semiconductor device according to claim 11, wherein the first inclination angle is larger than or equal to 35 degrees.

13. A method for manufacturing a semiconductor device, the method comprising:
forming a first groove in a main surface of a base portion to divide the main surface into a plurality of areas;
covering the main surface including the first groove with an insulating protective film;
cutting the base portion covered with the protective film along the first groove to divide the base portion into a plurality of detecting elements each having a first surface with a detector;
placing each of the detecting elements on a base member;
adhering a release film to a die having a cavity with a protrusion;
placing the die with respect to the base member while the first surface of the detecting elements is thrust into a portion of the release film on a surface of the protrusion;
filling the cavity of the die with a resin material; and
detaching the die and the release film from a resin package formed from the resin material after curing,
wherein at least a portion of an outer periphery of the surface of the protrusion is located outward from an outer periphery of the first surface when viewed in a direction in which the protrusion of the die and the first surface of the detecting element face each other.

14. The method for manufacturing a semiconductor device according to claim 13, further comprising:
after covering the main surface with the protective film and before cutting the base portion, forming a second groove with a smaller width than a bottom surface of the first groove along the bottom surface; and
cutting the base portion covered with the protective film along the first groove and the second groove so as to divide the base portion into the plurality of detecting elements.
